(19) United States
(12) Patent Application Publication
(10) Pub. No.: US 2015/0346050 A1
(43) Pub. Date: Dec. 3, 2015

(54) MULTILAYER ENCAPSULATION WITH INTEGRATED GAS PERMEATION SENSOR

(71) Applicant: Samsung SDI Co., Ltd., Yongin-si (KR)

(72) Inventors: Lorenza Moro, Palo Alto, CA (US); Damien S. Boesch, San Jose, CA (US)

(21) Appl. No.: 14/723,442

(22) Filed: May 27, 2015

Related U.S. Application Data
(60) Provisional application No. 62/006,035, filed on May 30, 2014.

(51) Int. Cl. G01M 3/04; H01L 51/52

(52) U.S. Cl. CPC G01M 3/04; H01L 51/5253

(57) ABSTRACT

Barrier stacks according to embodiments of the present invention provide early indication of barrier failure. In some embodiments, the barrier stack includes one or more dyads comprising a first polymer decoupling layer and a second barrier layer. The barrier stack includes one or more integrated gas permeation sensors between the first and second layers of one of the dyads, or between two of the dyads. In some embodiments, the barrier stack can include a primary barrier stack including one or more dyads, one or more integrated gas permeation sensor laterally spaced apart from the primary barrier stack, and a secondary barrier stack including one or more dyads on both the primary stack and the integrated gas permeation sensor(s).

### CROSS-REFERENCE TO RELATED APPLICATION(S)

This application claims priority to and the benefit of U.S. Provisional Application Ser. No. 62/006,035, filed on May 30, 2014 and titled GAS PERMEATION SENSOR INTEGRATED INTO MULTILAYER ENCAPSULATION, the entire content of which is incorporated herein by reference.

### BACKGROUND

Many devices, such as organic light emitting devices, organic thin film transistors, organic sensors, organic solar cells, and the like, are susceptible to degradation from the permeation of certain liquids and gases, such as water vapor and oxygen present in the environment, and other chemicals that may be used during the manufacture, handling or storage of the product. To reduce permeability to these damaging liquids, gases and chemicals, the devices are typically coated with a barrier coating or are encapsulated by incorporating a barrier stack adjacent one or both sides of the device.

Barrier coatings typically include a single layer of inorganic material, such as aluminum, silicon or aluminum oxides, or silicon nitrides. However, for many devices, a single layer barrier coating does not sufficiently reduce or prevent oxygen or water vapor permeability. Indeed, in organic light emitting devices, for example, which require exceedingly low oxygen and water vapor transmission rates, single layer barrier coatings do not adequately reduce or prevent the permeability of damaging gases, liquids and chemicals. Accordingly, in those devices (e.g., organic light emitting devices and the like), barrier stacks have been used in an effort to further reduce or prevent the permeation of damaging gases, liquids and chemicals.

In general, a barrier stack includes multiple dyads, each dyad being a two-layered structure including a barrier layer and a decoupling layer. The barrier stack can be deposited directly on the device to be protected, or may be deposited on a separate film or support, and then laminated onto the device. However, even when multiple dyads are used to encapsulate a sensitive device, defects or faults in one or more the layers of the dyad can allow infiltration of those gasses towards the encapsulated device. Accordingly, detection of the presence of those gasses within the encapsulation would be desirable.

### SUMMARY

According to embodiments of the present invention, a barrier stack includes one or more dyads, where each dyad includes a first layer including a polymer or organic material, and a second barrier layer. The second barrier layer of the barrier stack includes any suitable barrier layer, including, for example, an oxide barrier layer. The barrier stack also includes a gas permeation sensor integrated with the barrier stack. The gas permeation sensor is located between the layers of the barrier stack such that there is at least one intervening layer between the substrate or the device to be encapsulated by the barrier stack and the gas permeation sensor.

In some embodiments, the barrier stack may further include a fourth layer, where the first layer is on the fourth layer.

In some embodiments, the barrier layer includes an inorganic oxide barrier layer that includes an oxide of Al, Zr, Ti, Si, and combinations thereof. For example, the inorganic oxide barrier layer may include Al₂O₃ and/or SiO₂.

According to some embodiments, a method of making a barrier stack includes forming one or more dyads, where forming each of the dyads comprises forming a first layer comprising a polymer or organic material, and forming a barrier layer. The barrier layer may comprise an oxide barrier layer. The method further includes forming or positioning a gas permeation sensor either between the layers of one of the dyads, or between two of the dyads. The gas permeation sensor may be formed or positioned between any two layers or any two dyads so long as the gas permeation sensor is separated from the device to be encapsulated by at least one layer (e.g., by the polymer decoupling layer), or by at least one dyad (e.g., by at least one decoupling layer/bather layer couple).

The method may further include forming the first layer on a fourth layer. In embodiments including a fourth layer, the gas permeation sensor may be between any of the layers, including, for example, between the first layer (i.e., the polymer decoupling layer) and the fourth layer, or between the second layer (i.e., the barrier layer) and the fourth layer (e.g., when the fourth layer is deposited on the second layer of an underlying dyad, or when a fourth layer is deposited as a tie layer on the device to be encapsulated).

### BRIEF DESCRIPTION OF THE DRAWINGS

These and other features and advantages of the present invention will be better understood by reference to the following detailed description when considered in conjunction with the following drawings, in which:

FIGS. 1A through 1E are schematic views of barrier stacks according to embodiments of the present invention in which one or more gas permeation sensors are integrated in the barrier stacks at various locations;

FIG. 1F is a schematic view of a barrier stack according to embodiments of the present invention in which a gas permeation sensor is integrated in a secondary barrier stack;

FIGS. 2A through 2E are schematic views of barrier stacks according to embodiments of the present invention in which the barrier stack is deposited on a device to be encapsulated and in which one or more gas permeation sensors are integrated in the barrier stacks at various locations;

FIG. 2F is schematic view of a barrier stack according to embodiments of the present invention in which the barrier stack is deposited on a device to be encapsulated and in which a gas permeation sensor is integrated in a secondary barrier stack; and

FIGS. 3A through 3E are schematic views of barrier stacks according to embodiments of the present invention in which the barrier stacks include a fourth (tie) layer.

### DETAILED DESCRIPTION

In a multilayer barrier stack, permeating gasses travel through the layers of the stack following a path from the outermost layers towards the device encapsulated by the stack. The permeation occurs due to defects in the barrier layers which allow the gasses to permeate through those layers via the defects and reach the bulk polymer decoupling layers, through which the gasses permeate rather easily. Because the devices encapsulated by the stacks are sensitive to these gasses, once they permeate through the innermost layer, the gasses reach the encapsulated device and cause damage to the device. As such, barrier stacks have a limited time of effectiveness, termed the “lag time.” This mechanism of vapor permeation is described, e.g., in Graff et al., “Mechanisms of vapor permeation through multilayer barrier films: Lag time versus equilibrium permeation,” Journal of Applied Science, vol. 96, no. 4, pgs. 1840-1849 (2004), the entire content of which is incorporated herein by reference. Additionally, measurements supporting this mechanism are reported in Vogt et al., “X-ray and neutron reflectivity measurements of moisture transport through model multilayered barrier films for flexible displays,” Journal of Applied Physics, vol. 97, 114509 (2005), the entire content of which is incorporated herein by reference.

To detect when a barrier stack has reached its lag time, a gas permeation sensor can be positioned near the encapsulated device to provide an indication of the infiltration of gasses to the device. However, this scheme does not provide an early warning of failure, which early warning can be important in certain applications, such as, e.g., organic sensors deployed in the environment as part of the Internet-of-Things (“IoT”), thin film batteries, airplane cockpit display, medical equipment or military device applications. Accordingly, in some embodiments of the present invention, a multilayer barrier stack includes an integrated gas permeation sensor positioned a distance from the device being encapsulated by the stack. For example, in some embodiments, the gas permeation sensor is positioned between two layers of the multilayer barrier stack, and is separated from the device by at least one intervening layer between the sensor and the device.

In embodiments of the present invention, a barrier stack includes at least one dyad, where each dyad includes a barrier layer on a decoupling layer. The barrier stack also includes an integrated gas permeation sensor between two layers of the barrier stack. The gas permeation sensor can be positioned between any two layers of any dyad of the barrier stack or between any two dyads of the barrier stack so long as the gas permeation sensor and the device being encapsulated by the stack are separated by at least one layer (e.g., at least one discrete layer).

In some embodiments of the present invention, each of the dyads of the barrier stack includes a first layer that acts as a smoothing or planarization layer, and a second barrier layer that provides the barrier properties to the barrier stack. The barrier layer may include any suitable barrier layer, for example, an oxide layer (including an inorganic oxide barrier material). The layers of the barrier stack can be directly deposited on a device to be encapsulated (or protected) by the barrier stack, or may be deposited on a separate substrate or support, and then laminated on the device.

The first layer of the dyad includes a polymer or other organic material that serves as a planarization, decoupling and/or smoothing layer. Specifically, the first layer decreases surface roughness, and encapsulates surface defects, such as pits, scratches, digs and particles, thereby creating a planarized surface that is ideal for the subsequent deposition of additional layers. As used herein, the terms “first layer,” “smoothing layer,” “decoupling layer,” and “planarization layer” are used interchangeably, and all terms refer to the first layer, as now defined. The first layer can be deposited directly on the device to be encapsulated (e.g., an organic light emitting device), or may be deposited on a separate support. The first layer may be deposited on the device or substrate by any suitable deposition technique, some nonlimiting examples of which include vacuum processes and atmospheric processes. Some nonlimiting examples of suitable vacuum processes for deposition of the first layer include flash evaporation with in situ polymerization under vacuum, and plasma deposition and polymerization. Some nonlimiting examples of suitable atmospheric processes for deposition of the first layer include spin coating, ink jet printing, screen printing and spraying.

The first layer can include any suitable material capable of acting as a planarization, decoupling and/or smoothing layer. Some nonlimiting examples of suitable such materials include organic polymers, inorganic polymers, organometallic polymers, hybrid organic/inorganic polymer systems, and silicates. In some embodiments, for example, the material of the first layer may be an acrylate-containing polymer, an alkylacrylate-containing polymer (including but not limited to methacrylate-containing polymers), or a silicon-based polymer.

The first layer can have any suitable thickness such that the layer has a substantially planar and/or smooth layer surface. As used herein, the term “substantially” is used as a term of approximation and not as a term of degree, and is intended to account for normal variations and deviations in the measurement or assessment of the planar or smooth characteristic of the first layer. In some embodiments, for example, the first layer has a thickness of about 100 to 1000 nm.

The second layer of the dyad is the layer that operates as the barrier layer, preventing the permeation of damaging gases, liquids and chemicals to the encapsulated device. Indeed, as used herein, the terms “second layer” and “barrier layer” are used interchangeably. The second layer is deposited on the first layer, and deposition of the second layer may vary depending on the material used for the second layer. However, in general, any deposition technique and any deposition conditions can be used to deposit the second layer. For example, the second layer may be deposited using a vacuum process, such as sputtering, chemical vapor deposition, metalorganic chemical vapor deposition, plasma enhanced chemical vapor deposition, evaporation, sublimation, electron cyclotron resonance-plasma enhanced chemical vapor deposition, and combinations thereof.

In some embodiments, however, the second layer is deposited by AC or DC sputtering. For example, in some embodiments, the second layer is deposited by AC sputtering. The AC sputtering deposition technique offers the advantages of faster deposition, better layer properties, process stability, control, fewer particles and fewer arcs. The conditions of the AC sputtering deposition are not particularly limited, and as would be understood by those of ordinary skill in the art, the conditions will vary depending on the area of the target and the distance between the target and the substrate. In some exemplary embodiments, however, the AC sputtering conditions may include a power of about 3 to about 6 kW, for example about 4 kW, a pressure of about 2 to about 6 mTorr, for example about 4.4 mTorr, an Ar flow rate of about 80 to about 120 sccm, for example about 100 sccm, a target voltage of about 350 to about 550 V, for example about 480 V, and a track speed of about 90 to about 200 cm/min, for example about 141 cm/min. Also, although the inert gas used in the AC sputtering process can be any suitable inert gas (such as helium, xenon, krypton, etc.), in some embodiments, the inert gas is argon (Ar).

The material of the second layer is not particularly limited, and may be any material suitable for substantially preventing or reducing the permeation of damaging gases, liquids and chemicals (e.g., oxygen and water vapor) to the encapsulated device. Some nonlimiting examples of suitable materials for the second layer include metals, metal oxides, metal nitrides, metal oxynitrides, metal carbides, metal oxyborides, and combinations thereof. Those of ordinary skill in the art would be capable of selecting a suitable metal for use in the oxides, nitrides and oxynitrides based on the desired properties of the layer. However, in some embodiments, for example, the metal may be Al, Zr, Si, Zn, Sn or Ti.

The density and refractive index of the second layer is not particularly limited and will vary depending on the material of the layer. However, in some exemplary embodiments, the second layer may have a refractive index of about 1.6 or greater, e.g., 1.675. The thickness of the second layer is also not particularly limited. However, in some exemplary embodiments, the thickness is about 20 nm to about 100 nm, for example about 40 nm to about 70 nm. In some embodiments, for example, the thickness of the third layer is about 40 nm. As is known to those of ordinary skill in the art, thickness is dependent on density, and density is related to refractive index. See, e.g., Smith, et al., “Void formation during film growth: A molecular dynamics simulation study,” J. Appl. Phys., 79 (3), pgs. 1448-1457 (1996); Fabes, et al., “Porosity and composition effects in sol-gel derived interference filters,” Thin Solid Films, 254 (1995), pgs. 175-180; Jerman, et al., “Refractive index of this films of SiO2, ZrO2, and HfO2 as a function of the films' mass density,” Applied Optics, vol. 44, no. 15, pgs. 3006-3012 (2005); Mergel, et al., “Density and refractive index of TiO2 films prepared by reactive evaporation,” Thin Solid Films, 3171 (2000) 218-224; and Mergel, D., “Modeling TiO2 films of various densities as an effective optical medium,” Thin Solid Films, 397 (2001) 216-222, all of which are incorporated herein by reference. Also, the correlation between film density and barrier properties is described, e.g., in Yamada, et al., “The Properties of a New Transparent and Colorless Barrier Film,” Society of Vacuum Coaters, 505/856-7188, 38^{th} Annual Technical Conference Proceedings (1995) ISSN 0737-5921, the entire content of which is also incorporated herein by reference. Accordingly, those of ordinary skill in the art would be able to calculate the density of the second layer based on the refractive index and/or thickness information.

The gas permeation sensor may include any sensor suitable for detecting the permeation or infiltration, or more generally, the presence of damaging gasses (such as, e.g., water vapor and/or oxygen). Additionally, the gas permeation sensor may also provide any suitable indication of the presence of damaging gasses, such as visual indication or a change in a property, such as, e.g., a change in electrical resistance. The gas permeation sensor may also include additional functionalities, such as, e.g., capacitive touch sensing. Suitable gas permeation sensors for the detection of water vapor and/or oxygen (and similar damaging gasses) are known in the art, and described, for example, in U.S. Pat. No. 8,603,825 to Chua et al., the entire content of which is incorporated herein by reference.

The gas permeation sensor may be opaque, or alternatively may be made of a transparent material. Any suitable sensor materials may be used, nonlimiting examples of which include transparent conducting oxides, e.g., indium gallium zinc oxides, and similar materials. According to embodiments of the present invention, sensors made of a transparent material can be positioned within the barrier stack directly covering (albeit with at least one intervening layer) the device being encapsulated by the stack. Such transparent sensors can provide sensor coverage for the entire device area, thereby providing early permeation warnings for the entire area of the encapsulated device. Additionally, in some embodiments, although transparent sensors may be particularly useful for placement directly over (albeit with at least one intervening layer) the device being encapsulated, the transparent sensors may also be placed adjacent or next to the device.

In some embodiments, opaque sensors may be placed in any position within the barrier stack (i.e., as long as there is at least one intervening layer between the sensor and the encapsulated device) that is not directly covering the device. For example, opaque sensors (or transparent sensors, as discussed above) may be placed in any position next to or adjacent the device being encapsulated. For example, in some embodiments, the sensor (either opaque or transparent) may be placed within the barrier stack at a position offset from the position of the device.

Additionally, the barrier stack may include only one gas permeation sensor, or may include a plurality of gas permeation sensors. For example, in some embodiments, the barrier stack may include a single gas permeation sensor. The single gas permeation sensor may be positioned anywhere within the barrier stack so long as the sensor is separated from the device being encapsulated by at least one layer (e.g., at least one discrete layer of the barrier stack). However, in some embodiments, the single gas permeation sensor is positioned within the barrier stack next to or adjacent the device in order to more accurately detect failures in the barrier stack closest to the device. In some embodiments, for example, the single gas permeation sensor may include a transparent sensor positioned over the device, and may be large enough to cover the entire area of the underlying device.

According to some embodiments, the barrier stack includes a plurality of gas permeation sensors. In embodiments with a plurality of gas permeation sensors, the sensors may be placed in any pattern or arrangement around the device or within the barrier stack. For example, in some embodiments, the plurality of sensors may be positioned between the same two layers of the barrier stack but in different positions around the device being encapsulated. Alternatively, the sensors may be positioned in the same lateral direction relative to the device, but between different layers of the barrier stack. Embodiments in which multiple sensors are positioned between different layers of the barrier stack can provide additional information about the lag time and failure rate of the encapsulation. According to some embodiments, the sensors may be placed both in different positions around the device and between different layers of the barrier stack. Embodiments in which multiple sensors are placed in different lateral positions relative to the device as well as between different layers of the barrier stacks provide also provide additional information about the lag time and failure modes of the barrier stack, and can be useful in pinpointing the cause or location of the failure.

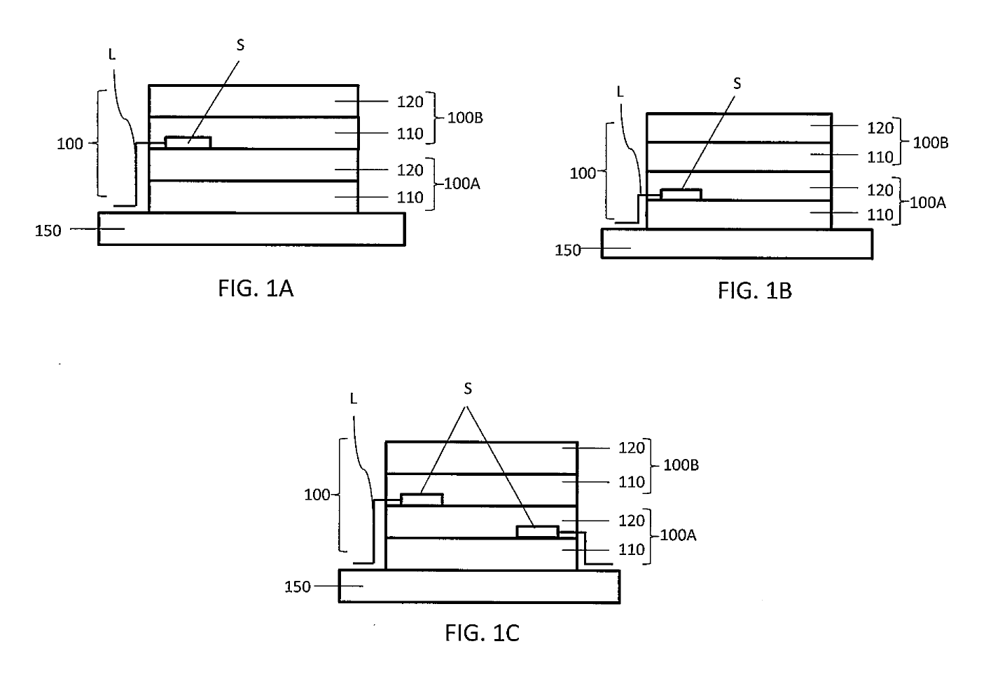

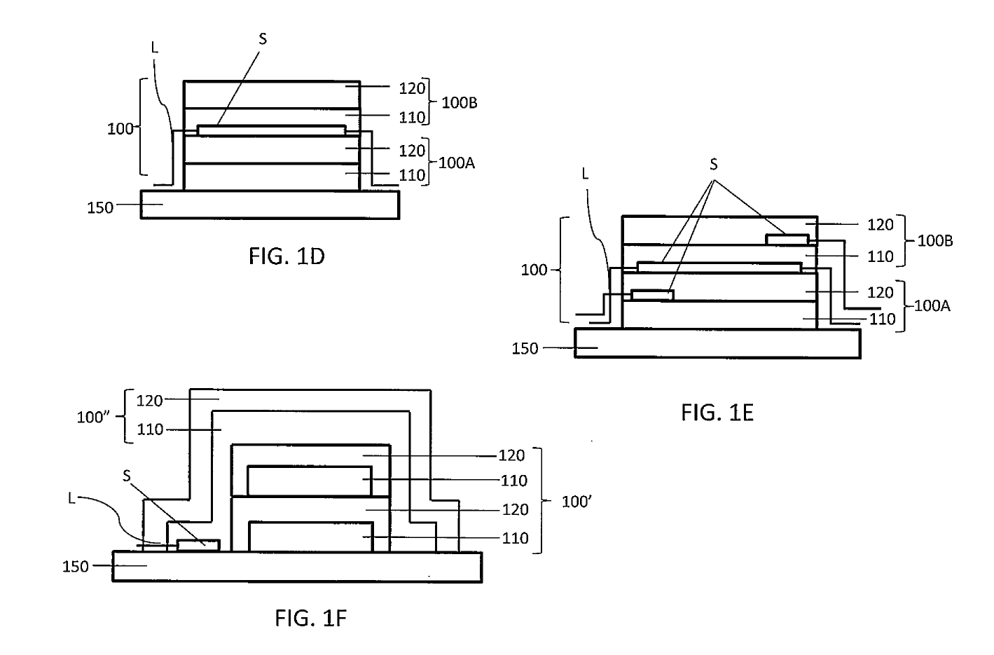

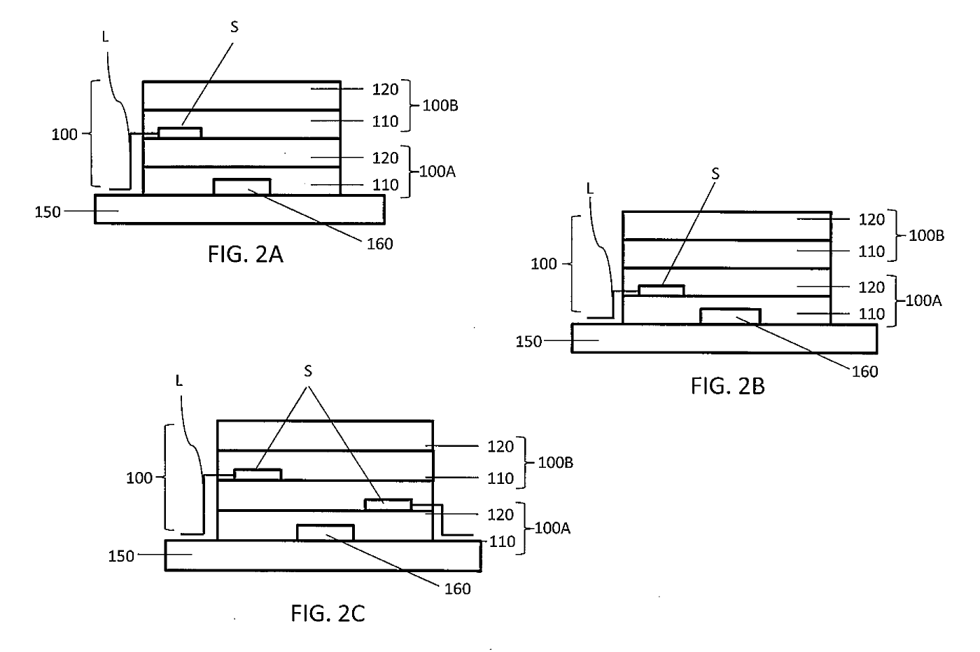

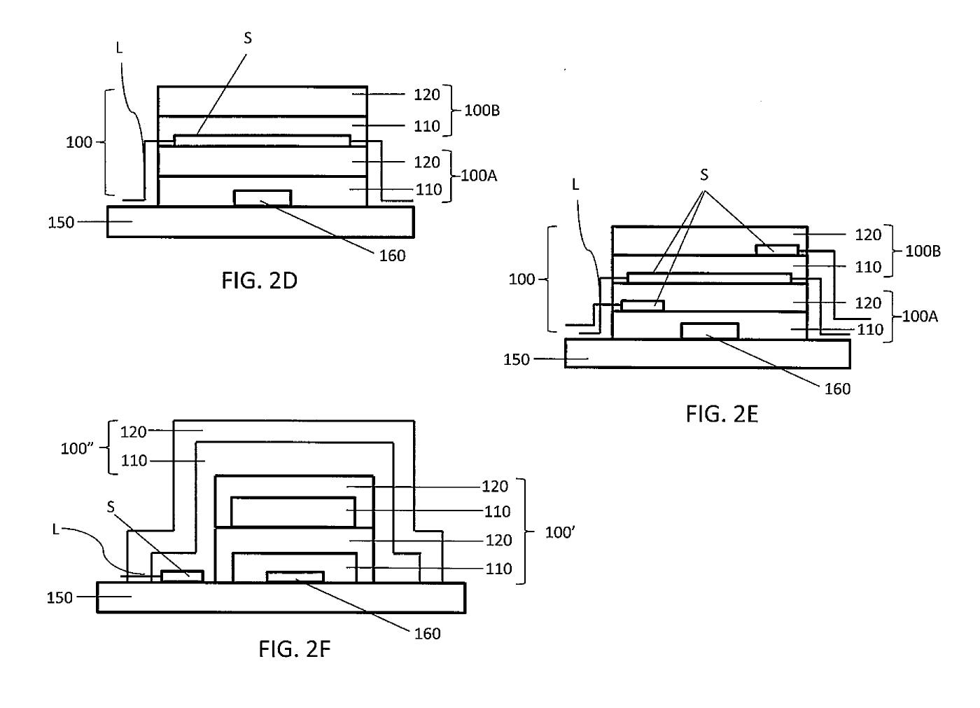

Exemplary embodiments of a barrier stack according to the present invention are illustrated in FIGS. 1A-1E and 2A-2E. The barrier stacks 100 depicted in FIGS. 1A-1E include first and second dyads 100A and 100B, each including a first layer 110 which includes a decoupling layer or smoothing layer (i.e., the first layer discussed above), and a barrier layer 120. The barrier stacks 100 also include one or more integrated gas permeation sensors S, each of which is attached to at least one sensor lead L. While FIGS. 1A-1E and FIGS. 2A-2E depict two dyads, it is understood that the barrier stack need not have two dyads, and can have only one dyad, or more than two dyads. In FIGS. 1A-1E, the barrier stack 100 is deposited on a substrate 150, for example glass or plastic (such as, for example, polyethylene naphthalate (PEN) or polyethylene terephthalate (PET)). However, in FIGS. 2A-2E, the barrier stack 100 is deposited directly on the device 160, e.g., an organic light emitting device.

As shown in FIGS. 1A-1C and FIGS. 2A-2C, the gas permeation sensor(s) S may be positioned within the barrier stack at any of various positions, including (but not limited to) between the dyads 100A and 100B (as shown in FIGS. 1A and 2A), or between the first layer 110 and second layer 120 of one of the dyads (as shown, for example, in FIGS. 1B and 2B). Additionally, as shown, for example, in FIGS. 1C and 2C, the barrier stack may include multiple sensors S. For example, as shown in FIGS. 1C and 2C, the sensors S may be positioned in the barrier stack at positions that are different laterally with respect to the substrate, as well as between different layers of the barrier stack. Also, while two sensors S are shown in FIGS. 1C and 2C between the first and second layers of one dyad and between the dyads, it is understood that any number of sensors may be used and may be positioned anywhere within the barrier stack so long as there is at least one layer between the substrate (in FIGS. 1A-1C) or device (in FIGS. 2A-2C).

Also, as shown in FIGS. 1D and 2D, the sensor may be a transparent sensor TS, and may cover a larger area, for example, the entire area of the device (as shown in FIG. 2D), or the entire expected display (or device) area (as shown in FIG. 1D). Additionally, according to some embodiments, as shown in FIGS. 1E and 2E, the barrier stack may include a combination of transparent sensors TS and sensors S (which may be opaque, and therefore have a smaller area). Although, FIGS. 1E and 2E depict one transparent sensor TS between the dyads of the stack, and two sensors S between the first and second layers of each of the dyads, it is understood that any number of sensors S and/or transparent sensors TS may be used and may be positioned anywhere within the barrier stack so long as there is at least one layer between the substrate (in FIGS. 1D and 1E) or device (in FIGS. 2D and 2E).

According to some embodiments of the present invention, the sensor S may be deposited on the substrate at a lateral position offset from the position of the device (or the position for the device is expected to be placed). A shown in FIGS. 1F and 2F, in embodiments in which a sensor S is deposited on the substrate, the barrier stack may include a primary barrier stack 100′ that covers the device (or the area where the device is expected to be placed) but not the sensor S, and a secondary stack 100″ that covers both the primary stack 100′ and the sensor(s) S. In this manner, the sensor S may be located on the substrate but still be separated (laterally) from the device by at least one layer. Sensors S positioned on the substrate in this manner enable detection of gasses permeating through the substrate.

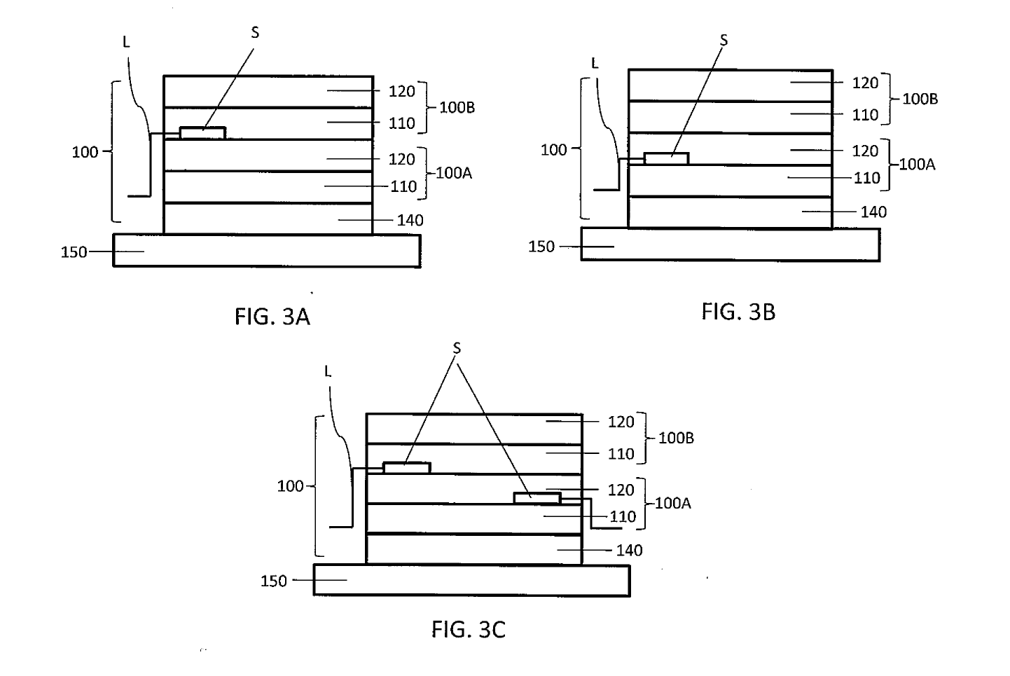

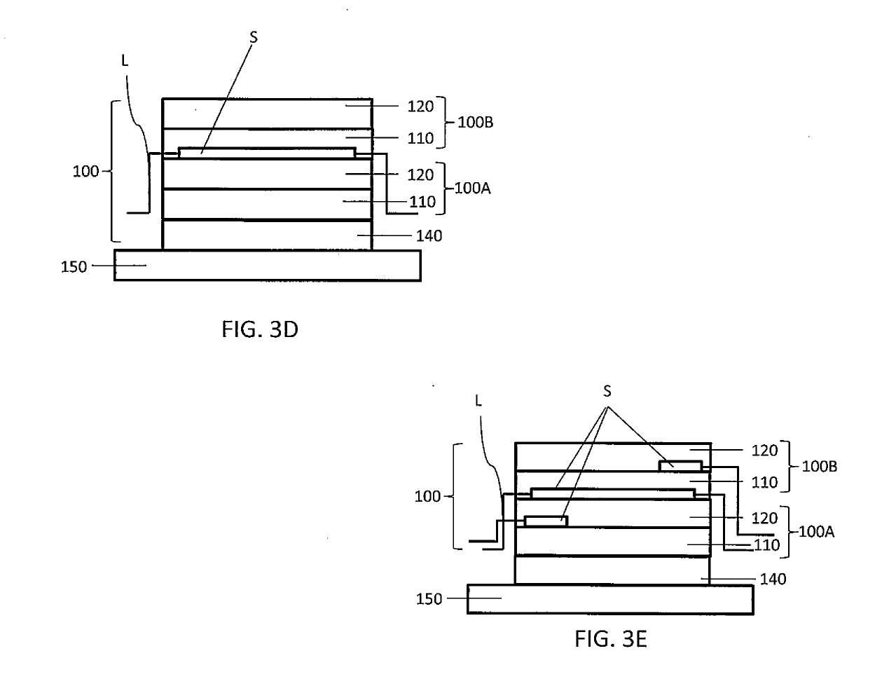

In addition to the first layer 110 and barrier layer 120 making up a dyad, some exemplary embodiments of the barrier stack 100 can include a fourth layer 140 between the first layer 110 and the substrate 150 or the device 160 to be encapsulated. Although the inventive barrier stacks are discussed herein and depicted in the accompanying drawings as including, for example, a “first” layer and a “fourth” layer 140, it is understood that the layers of the barrier stack may be deposited on the substrate 150 or the device 160 in any order, and the identification of the first and fourth layers as “first” and “fourth,” respectively, does not mean that these layers must be deposited in that order. Indeed, as discussed here, and depicted in FIGS. 3A-3E, in some embodiments, the fourth layer 140 is deposited on the substrate 150 or device 160 prior to deposition of the first layer 110.

The fourth layer 140 acts as a substrate tie layer, improving adhesion between the layers of the barrier stack 100 and the substrate 150 or the device 160 to be encapsulated. In particular, the fourth layer 140 is typically the first layer deposited on the substrate, prior to deposition of the first layer 110 (i.e., the polymer decoupling layer), and acts to improve adhesion of the first layer to the substrate or device for encapsulation. The material of the fourth layer 140 is not particularly limited, and can include the materials described above with respect to the inner oxide barrier layer 120. Also, the material of the fourth layer may be the same as or different from the material of the inner oxide barrier layer 120. The materials of the inner oxide barrier layer 120 are described in detail above.

Additionally, the fourth layer may be deposited on the substrate or the device to be encapsulated by any suitable technique, including, but not limited to the techniques described above with respect to the inner oxide barrier layer. In some embodiments, for example, the fourth layer may be deposited by AC or DC sputtering under conditions similar to those described above for the inner oxide barrier layer. Also, the thickness of the deposited fourth layer is not particularly limited, and can be any thickness suitable to effect good adhesion between the first layer of the barrier stack and the substrate or device to be encapsulated. In some embodiments, for example, the fourth (substrate tie) layer can have a thickness of about 20 nm to about 60 nm, for example, about 40 nm.

Exemplary barrier stacks 100 including a fourth layer 140 according to embodiments of the present invention are depicted in FIGS. 3A-3E. The barrier stacks 100 depicted in FIGS. 3A-3E include first and second dyads 100A and 100B, each including a first layer 110 which includes a decoupling layer, a fourth layer 140 which includes a substrate tie layer, and a barrier layer 120. The barrier stacks 100 also include one or more integrated gas permeation sensors S, each of which is attached to a corresponding sensor lead L. While FIGS. 3A-3E depict two dyads, it is understood that the barrier stack need not have two dyads, and can have only one dyad, or more than two dyads. In FIGS. 3A-3E, the barrier stack 100 is deposited on a substrate 150, for example glass or plastic (e.g., PET or PEN). However, it is understood that the barrier stack 100 can alternatively be deposited directly on the device 160, e.g., an organic light emitting device, as depicted in FIGS. 2A-2E with respect to the embodiments excluding the fourth layer.

Also, the barrier stacks including a fourth layer also include a sensor or a plurality of sensors integrated in the stack. The sensors S and/or transparent sensors TS may be arranged in any manner within the barrier stack and laterally around the substrate or device, as depicted generally in FIGS. 3A-3E, and described above with respect to FIGS. 1A-1E and 2A-2E.

In some embodiments of the present invention, a method of making a barrier stack includes providing a substrate 150, which may be a separate substrate support or may be a device 160 for encapsulation by the barrier stack 100 (e.g., an organic light emitting device or the like). The method further includes forming a first layer 110 on the substrate. The first layer 110 is as described above and acts as a decoupling/smoothing/planarization layer. As also discussed above, the first layer 110 may be deposited on the device 160 or substrate 150 by any suitable deposition technique, including, but not limited to, vacuum processes and atmospheric processes. Some nonlimiting examples of suitable vacuum processes for deposition of the first layer include flash evaporation with in situ polymerization under vacuum, and plasma deposition and polymerization. Some nonlimiting examples of suitable atmospheric processes for deposition of the first layer include spin coating, ink jet printing, screen printing and spraying.

The method further includes depositing a second layer 120 on the surface of the first layer 110. The second layer 120 is as described above and acts as the barrier layer of the barrier stack, serving to substantially prevent or substantially reduce the permeation of damaging gases, liquids and chemicals to the underlying device. The deposition of the second layer 120 may vary depending on the material used for the second layer. However, in general, any deposition technique and any deposition conditions can be used to deposit the second layer. For example, the second layer 120 may be deposited using a vacuum process, such as sputtering, chemical vapor deposition, metalorganic chemical vapor deposition, plasma enhanced chemical vapor deposition, evaporation, sublimation, electron cyclotron resonance-plasma enhanced chemical vapor deposition, and combinations thereof. In some embodiments, however, the second layer 120 is deposited by AC or DC sputtering, for example pulsed AC or pulsed DC sputtering. While any suitable conditions for deposition can be employed, some suitable conditions are described above.

In some embodiments, the method further includes depositing a fourth layer 140 between the substrate 150 (or the device 160 to be encapsulated) and the first layer 110. The fourth layer 140 is as described above and acts as a tie layer for improving adhesion between the substrate or device and the first layer 110 of the barrier stack 100. The fourth layer 140 may be deposited by any suitable technique, as discussed above. For example, as also discussed above, the fourth layer 140 may be deposited on the substrate 150 (or the device 160 to be encapsulated) by AC or DC sputtering, e.g., pulsed AC or pulsed DC sputtering.

As discussed above, according to embodiments of the present invention, a barrier stack includes at least one dyad and a gas permeation sensor integrated in the barrier stack. The gas permeation sensor is separated from the substrate on which the barrier stack is deposited (or the device encapsulated by the barrier stack) by at least one layer (e.g., a discrete layer of the barrier stack). The integrated gas permeation sensor separated from the substrate (or device) by at least one layer provides early detection of barrier failure. For example, while gas permeation sensors that are located at the same level as the device may provide an indication that the barrier has already failed (i.e., that gasses have already reached the encapsulated device), the integrated gas permeation sensors that are separated from the device by at least one layer provide an early indication that failure may be imminent.

While certain exemplary embodiments of the present invention have been illustrated and described, it is understood by those of ordinary skill in the art that certain modifications and changes can be made to the described embodiments without departing from the spirit and scope of the present invention.

What is claimed is:

1. A barrier stack, comprising:
one or more dyads, each dyad comprising a first layer comprising a polymer or organic material, and a second layer comprising a barrier layer; and
one or more integrated gas permeation sensors either between the first layer and the second layer of one of the dyads, or between two of the dyads.

2. The barrier stack of claim 1, wherein the one or more integrated gas permeation sensors comprises one or more transparent sensors.

3. The barrier stack of claim 1, wherein the one or more integrated gas permeation sensors comprises a plurality of gas permeation sensors positioned at different lateral locations within the barrier stack.

4. The barrier stack of claim 1, wherein the one or more integrated gas permeation sensors comprises a plurality of gas permeation sensors positioned between different layers of the barrier stack.

5. The barrier stack of claim 1, further comprising a fourth layer, wherein the first layer is on the fourth layer.

6. The barrier stack of claim 1, wherein the barrier layer comprises an oxide of Al, Zr, Ti, Si, and combinations thereof.

7. The barrier stack of claim 1, wherein the barrier layer comprises Al₂O₃ and/or SiO₂.

8. A method of making a barrier stack, comprising:
forming one or more dyads, wherein forming each of the dyads comprises forming a first layer comprising a polymer or organic material, and forming a second layer comprising a barrier layer; and
depositing one or more integrated gas permeation sensors either between the first and second layers of one of the dyads, or between two of the dyads.

9. The method of claim 8, wherein the depositing the one or more integrated gas permeation sensors comprises depositing one or more transparent sensors.

10. The method of claim 8, wherein the depositing the one or more integrated gas permeation sensors comprises depositing a plurality of gas permeation sensors at different lateral locations within the barrier stack.

11. The barrier stack of claim 8, wherein the depositing the one or more integrated gas permeation sensors comprises depositing a plurality of gas permeation sensors between different layers of the barrier stack.

12. The method of claim 8, further comprising forming the first layer on a fourth layer.

13. The method of claim 8, wherein the barrier layer comprises an oxide of Al, Zr, Ti, Si, and combinations thereof.

14. The method of claim 8, wherein the barrier layer comprises Al₂O₃ and/or SiO₂.

15. A barrier stack, comprising:
a primary barrier stack comprising one or more first dyads, each first dyad comprising a first layer comprising a polymer or organic material, and a second layer comprising a barrier layer;
one or more integrated gas permeation sensors laterally spaced apart from the primary barrier stack; and
a secondary barrier stack on both the primary barrier stack and the one or more integrated gas permeation sensors, the secondary barrier stack comprising one or more second dyads, each second dyad comprising a first layer comprising a polymer or organic material, and a second layer comprising a barrier layer.

16. The barrier stack of claim 15, wherein the one or more integrated gas permeation sensors comprises one or more transparent sensors.

17. The barrier stack of claim 15, wherein the one or more integrated gas permeation sensors comprises a plurality of gas permeation sensors positioned at different lateral locations spaced apart from the primary bather stack.

18. The barrier stack of claim 15, further comprising one or more second integrated gas permeation sensors positioned between different layers of either the primary barrier stack or the secondary barrier stack.
